(19) United States
(12) Patent Application Publication
(10) Pub. No.: US 2015/0125603 A1
(43) Pub. Date: May 7, 2015

(54) METHODS AND APPARATUS FOR DEPOSITING CHALCOGENIDE LAYERS USING HOT WIRE CHEMICAL VAPOR DEPOSITION

(71) Applicant: APPLIED MATERIALS, INC., Santa Clara, CA (US)

(72) Inventor: SUKTI CHATTERJEE, Cupertino, CA (US)

(21) Appl. No.: 14/533,648

(22) Filed: Nov. 5, 2014

Related U.S. Application Data
(60) Provisional application No. 61/900,157, filed on Nov. 5, 2013.

(51) Int. Cl. C23C 16/30; C23C 16/455; C23C 16/448; C23C 16/06

(52) U.S. Cl. CPC C23C 16/305; C23C 16/06; C23C 16/45557; C23C 16/448
USPC 427/248.1

(57) ABSTRACT

Methods and apparatus for depositing chalcogenide materials on substrates in a hot wire chemical vapor deposition (HWCVD) process are provided herein. In some embodiments, a method of depositing a chalcogenide film atop a substrate in a hot wire chemical vapor deposition (HWCVD) process chamber includes vaporizing one or more liquid chalcogenide precursors while flowing a carrier gas to form a first gas mixture of the vaporized chalcogenide precursor and the carrier gas; mixing the first gas mixture with a second gas to form a second gas mixture, wherein the second gas is a catalyst; and flowing the second gas mixture to the HWCVD process chamber, wherein the second gas mixture dissociates in the HWCVD process chamber to deposit a chalcogenide film atop the substrate.

### CROSS-REFERENCE TO RELATED APPLICATIONS

This application claims benefit of U.S. provisional patent application Ser. No. 61/900,157, filed Nov. 5, 2013, which is herein incorporated by reference in its entirety.

### FIELD

Embodiments of the present disclosure generally relate to methods and apparatus for depositing chalcogenide materials on substrates.

### BACKGROUND

The inventors have observed that chalcogenide materials can be used as phase change materials in semiconductor applications. Chalcogenide materials can be deposited using typical physical vapor deposition and chemical vapor deposition processes. However, the inventors have observed that such deposition processes result in low film growth rate and non-conformal growth on three dimensional structures.

Therefore, the inventors have provided improved methods for depositing chalcogenide materials on substrates.

### SUMMARY

Methods and apparatus for depositing materials on substrates in a hot wire chemical vapor deposition (HWCVD) process are provided herein. In some embodiments, a method of depositing a chalcogenide film atop a substrate in a hot wire chemical vapor deposition (HWCVD) process chamber includes vaporizing one or more liquid chalcogenide precursors while flowing a carrier gas to form a first gas mixture of the vaporized chalcogenide precursor and the carrier gas; mixing the first gas mixture with a second gas to form a second gas mixture, wherein the second gas is a catalyst; and flowing the second gas mixture to the HWCVD process chamber, wherein the second gas mixture dissociates in the HWCVD process chamber to deposit a chalcogenide film atop the substrate.

In some embodiments, a method of depositing a chalcogenide film atop a substrate in a hot wire chemical vapor deposition (HWCVD) process chamber includes vaporizing one or more liquid chalcogenide precursors while flowing a carrier gas to form a first gas mixture of the vaporized chalcogenide precursor and the carrier gas, wherein a flow rate of the carrier gas is about 100 sccm to about 2,000 sccm; mixing the first gas mixture with a second gas to form a second gas mixture, wherein the second gas is a catalyst, wherein a flow rate of the second gas is about 100 sccm to about 1,000 sccm; heating filaments of the HWCVD process chamber to a temperature of about 500 degrees Celsius to about 600 degrees Celsius; and flowing the second gas mixture to the HWCVD process chamber, wherein the second gas mixture dissociates in the HWCVD process chamber to deposit a chalcogenide film atop the substrate.

In some embodiments, the disclosure may be embodied in a computer readable medium having instructions stored thereon that, when executed, cause a method to be performed in a process chamber, the method includes any of the embodiments disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow chart for a method of depositing a chalcogenide film in accordance with some embodiments of the present disclosure.

FIG. 2 depicts a schematic side view of a substrate processing system in accordance with some embodiments of the present disclosure.

FIG. 3 depicts a schematic side view of a HWCVD process chamber in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present disclosure provide hot wire chemical vapor deposition (HWCVD) processing techniques useful for depositing chalcogenide films. In one exemplary application, embodiments of the present disclosure may advantageously be used to deposit chalcogenide films while providing one or more of the following benefits: high film growth rate, conformal growth on three dimensional structures, decoupling substrate temperature from precursor decomposition, and control of the composition of the chalcogenide film. Embodiments of the present disclosure may be used advantageously in forming memory applications such as a phase change memory cell, a rewritable optical disk, or the like.

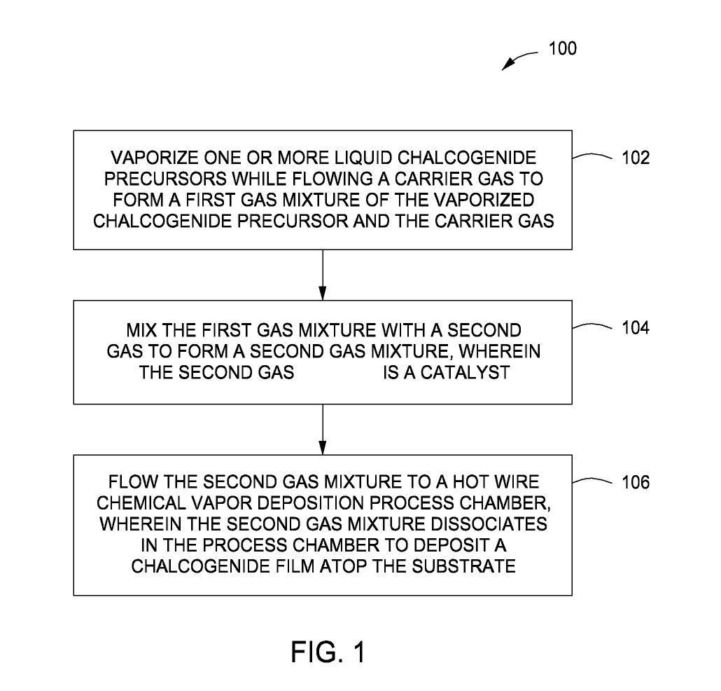

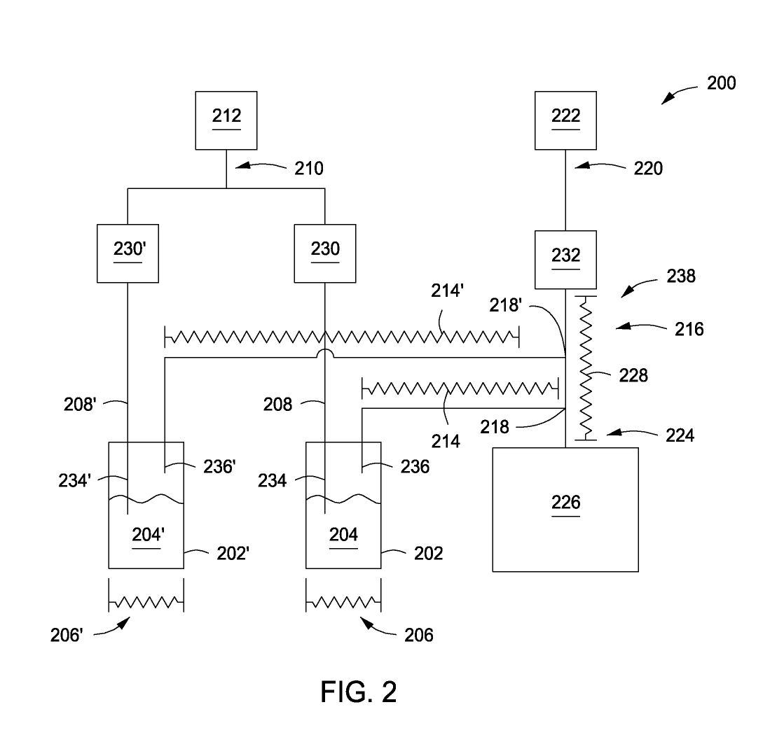

FIG. 1 depicts a flow chart for a method 100 of depositing a chalcogenide film atop a substrate in a hot wire chemical vapor deposition (HWCVD) process chamber. FIG. 2 depicts a schematic side view of an illustrative substrate processing system used to perform the method of FIG. 1 in accordance with some embodiments of the present disclosure.

The method begins at 102 by vaporizing one or more liquid chalcogenide precursors while flowing a carrier gas to form a first gas mixture of the vaporized chalcogenide precursor and the carrier gas. In some embodiments, the chalcogenide precursors may be germanium (Ge), antimony (Sb) and tellurium (Te) and alkyl, cycloalkyl, alkenyl (vinyl, allyl, etc), alkylsilyl, or aryl precursors of Ge, Sb and Te. In some embodiments, the chalcogenide precursors may be at least one of Ge(NMe₂)₄, Sb(NMe₂)₃, or Te(i-Pr)₂. The carrier gas is an inert gas, such as nitrogen, helium, argon or the like.

As depicted in FIG. 2, the liquid chalcogenide precursor 204 (i.e. precursor 204) is stored in an ampoule 202. In some embodiments, heat may be applied over portions of the substrate processing system 200 to vaporize the precursor and/or to maintain the precursor in a vaporized state. For example, a heat source 206 is coupled to the ampoule 202 to vaporize the precursor 204. The heat source 206 may be any heat source 206 suitable for vaporizing the precursor 204 in the ampoule 202, such as heating tape, a forced air heated cabinet, a heat exchanger, or the like.

In some embodiments, more than one precursor may be used in the substrate processing system 200. In such embodiments, each precursor may be stored in a separate ampoule and heated by the same heat source or a different heat source. For example, as depicted in FIG. 2, a second precursor 204′ is stored in a second ampoule 202′. A heat source 206′ is coupled to the second ampoule 202′ to vaporize the second precursor 204′. As described above, the heat source 206′ may be any heat source 206′ suitable for vaporizing the second precursor 204′ in the second ampoule 202′.

A carrier gas may be provided from a carrier gas source 212 disposed upstream of the ampoule 202. A first conduit 208 used to draw a vapor of the precursor 204 from the ampoule 202 into the first conduit 208 comprises a first end 210 coupled to the carrier gas source 212. Similarly, in embodiments having more than one precursor, a conduit 208′ used to draw a vapor of the second precursor 204′ from the second ampoule 202′ into the conduit 208′ comprising a first end 210 coupled to the carrier gas source 212.

In some embodiments, the flow of the carrier gas may be controlled by a first flow controller 230. The first flow controller 230 may be coupled to the first conduit 208 between the first end 210 of the first conduit 208 and the ampoule 202. The first flow controller 230 may be a mass flow controller or the like. In some embodiments, the flow rate of the carrier gas is about 100 sccm to about 2,000 sccm. Similarly, a flow controller 230′ coupled to the conduit 208′ between the first end 210 and the second ampoule 202′ may be used to control the flow of the carrier gas to the second ampoule 202′,

The first conduit 208 may be coupled to the ampoule 202 such that the first conduit 208 enters the volume of the ampoule 202 and has a first end 234 disposed beneath the surface of the precursor 204. The carrier gas may bubble through the precursor 204 to carry vapor and/or small droplets of the precursor 204 within the gas stream as a first gas mixture. A second end 236 may be disposed above the precursor 204 to receive the first gas mixture of the carrier gas and precursor. Alternatively, the first end 234 may be disposed above the surface of the liquid precursor. In embodiments having more than one precursor, the conduit 208′, having a first end 234′ and a second end 236′, may be coupled to the second ampoule 202′ in the same manner described above.

A heat source 214 may be configured to heat at least a first portion of the first conduit 208 from the ampoule 202 to the first junction 218 at the second conduit 216. The heat source 214 may be any heat source, as described above, suitable for maintaining the precursor in a vaporized state. Similarly, a heat source 214′ may be configured to heat at least a first portion of the conduit 208′ from the second ampoule 202′ to the junction 218′ at the second conduit 216. The heat source 214 may be the same heat source as the heat source 206 described above or a different heat source.

Next at 104, the first gas mixture is mixed with a second gas to form a second gas mixture. In some embodiments, the second gas is a catalyst to provide energy to the first gas mixture to help the process reaction within the HWCVD process chamber. In some embodiments, the second gas is hydrogen gas (H₂).

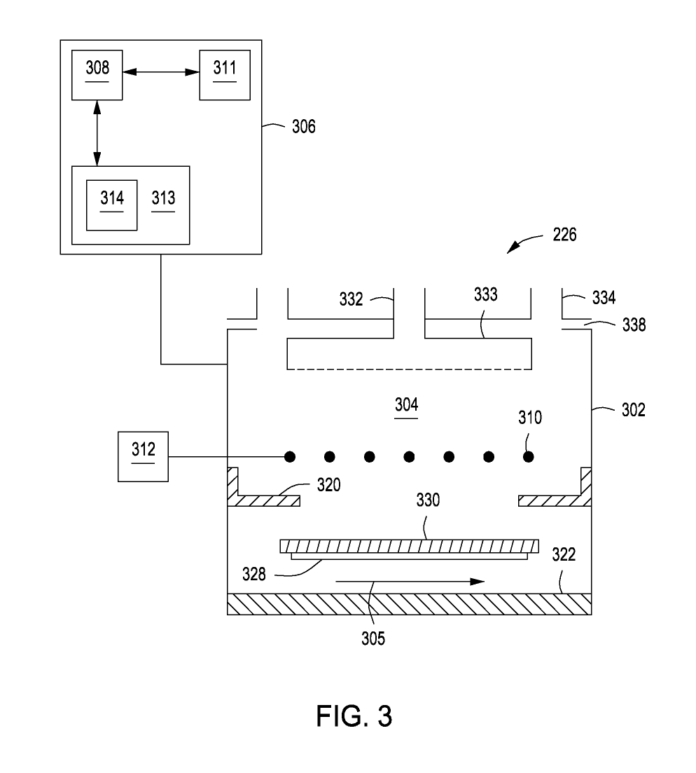

As depicted in FIG. 2, the second gas is provided from a second gas source 222. A second conduit 216 is coupled to the second gas source 222 at a first end 220 and is coupled to the first conduit 208 at a first junction 218 and to the conduit 208′ at a junction 218′ located downstream of the ampoules 202, 202′. As used herein, the term “junction” refers to the intersection of multiple flow paths or sections of conduit, such as by a T-shaped joint or section of conduit, a selective valve such as a valve which allows for the selection of either a first or second path, or the like. The second conduit 216 may have a second end 224 coupled to a HWCVD process chamber 226, such as the HWCVD process chamber described below with respect to FIG. 3.

A heat source 228 may be provided proximate to the second conduit to maintain the precursor in the second gas mixture in a vaporized state within the second conduit. The heat source 228 may be any heat source, as described above, suitable for maintaining the precursor in a vaporized state. As depicted in FIG. 2, the heat source 228 may be configured to heat only a second portion 238 of the second conduit 216, where the second portion 238 includes the first junction 218 and the junction 218′. The second portion 238 may extend on both sides of the junctions 218, 218′ as illustrated in FIG. 2, or may extend only downstream of the junctions 218, 218′ (not shown). The second portion 238 of the second conduit 216 may include the portion where the first gas mixture received from the first conduit 208 mixes with the second gas to form the second gas mixture. The heat source 228 may be the same heat source as the heat source 206 and/or the heat source 214 described above or a different heat source.

The second conduit 216 may include a second flow controller 232 coupled to the second conduit 216. In some embodiments, the second flow controller 232 is disposed between the first end 220 of the second conduit 216 and the first junction 218, or upstream of the first junction 218. For example, as depicted in FIG. 2, the second flow controller 232 provides the second gas at a desired flow rate to mix with the first gas mixture in the second portion 238 of the second conduit 216. In some embodiments, the flow rate of the second gas is about 100 sccm to about 1,000 sccm.

Next at 106, the second gas mixture flows to the HWCVD process chamber 226. The second gas mixture dissociates in the HWCVD process chamber 226 to deposit a chalcogenide film atop a substrate disposed within the HWCVD process chamber 226. The chalcogenide film may be a part of a device being fabricated on the substrate, such as a phase change memory cell, rewriteable optical disks, or the like.

As described below with respect to FIG. 3, the HWCVD process chamber 226 comprises a plurality of filaments, or wires, 310. The plurality of filaments 310 are heated to a temperature suitable to dissociate the second gas mixture and deposit a chalcogenide film atop the substrate 330. For example, the plurality of filaments 310 may be heated to a temperature of about 500 to about 600 degrees Celsius. In the method 100 described herein, the deposition of the chalcogenide film atop the substrate 330 is independent of the substrate temperature. In some embodiments, the pressure within the HWCVD process chamber 226 during the chalcogenide film formation is about 1 Torr to about 30 Torr, for example about 10 Torr.

FIG. 3 depicts a schematic side view of an HWCVD process chamber 226 (i.e. process chamber 226) suitable for use in accordance with embodiments of the present disclosure. The process chamber 226 generally comprises a chamber body 302 having an internal processing volume 304. A plurality of filaments are disposed within the chamber body 302 (e.g., within the internal processing volume 304). The plurality of wires 310 may also be a single wire routed back and forth across the internal processing volume 304. The plurality of wires 310 comprise a HWCVD source. The wires 310 are typically made of tungsten, although tantalum or iridium may also be used. Each wire 310 is clamped in place by support structures (not shown) to keep the wire taught when heated to high temperature, and to provide electrical contact to the wire. A power supply 312 is coupled to the wire 310 to provide current to heat the wire 310. A substrate 330 may be positioned under the HWCVD source (e.g., the wires 310), for example, on a substrate support 328. The substrate support 328 may be stationary for static deposition, or may move (as shown by arrow 305) for dynamic deposition as the substrate 330 passes under the HWCVD source.

The chamber body 302 further includes one or more gas inlets (one gas inlet 332 shown) to provide one or more process gases and one or more outlets (two outlets 334 shown) to a vacuum pump to maintain a suitable operating pressure within the process chamber 226 and to remove excess process gases and/or process byproducts. The gas inlet 332 may feed into a shower head 333 (as shown), or other suitable gas distribution element, to distribute the gas uniformly, or as desired, over the wires 310.

In some embodiments, one or more shields 320 may be provided to minimize unwanted deposition on interior surfaces of the chamber body 302. Alternatively or in combination, one or more chamber liners 322 can be used to make cleaning easier. The use of shields, and liners, may preclude or reduce the use of undesirable cleaning gases, such as the greenhouse gas NF₃. The shields 320 and chamber liners 322 generally protect the interior surfaces of the chamber body from undesirably collecting deposited materials due to the process gases flowing in the chamber. The shields 320 and chamber liners 322 may be removable, replaceable, and/or cleanable. The shields 320 and chamber liners 322 may be configured to cover every area of the chamber body that could become coated, including but not limited to, around the wires 310 and on all walls of the coating compartment. Typically, the shields 320 and chamber liners 322 may be fabricated from aluminum (Al) and may have a roughened surface to enhance adhesion of deposited materials (to prevent flaking off of deposited material). The shields 320 and chamber liners 322 may be mounted in the desired areas of the process chamber, such as around the HWCVD sources, in any suitable manner. In some embodiments, the source, shields, and liners may be removed for maintenance and cleaning by opening an upper portion of the deposition chamber. For example, in some embodiments, the a lid, or ceiling, of the deposition chamber may be coupled to the body of the deposition chamber along a flange 338 that supports the lid and provides a surface to secure the lid to the body of the deposition chamber.

A controller 306 may be coupled to various components of the process chamber 226 to control the operation thereof. Although schematically shown coupled to the process chamber 226, the controller may be operably connected to any component that may be controlled by the controller, such as the power supply 312, a gas supply (not shown) coupled to the gas inlet 332, a vacuum pump and or throttle valve (not shown) coupled to the outlet 334, the substrate support 328, and the like, in order to control the HWCVD deposition process in accordance with the methods disclosed herein. The controller 306 generally comprises a central processing unit (CPU) 308, a memory 313, and support circuits 311 for the CPU 308. The controller 306 may control the process chamber 226 directly, or via other computers or controllers (not shown) associated with particular support system components. The controller 306 may be one of any form of general-purpose computer processor that can be used in an industrial setting for controlling various chambers and sub-processors. The memory, or computer-readable medium, 313 of the CPU 308 may be one or more of readily available memory such as random access memory (RAM), read only memory (ROM), floppy disk, hard disk, flash, or any other form of digital storage, local or remote. The support circuits 311 are coupled to the CPU 308 for supporting the processor in a conventional manner. These circuits include cache, power supplies, clock circuits, input/output circuitry and subsystems, and the like. Inventive methods as described herein may be stored in the memory 313 as software routine 314 that may be executed or invoked to turn the controller into a specific purpose controller to control the operation of the process chamber 226 in the manner described herein. The software routine may also be stored and/or executed by a second CPU (not shown) that is remotely located from the hardware being controlled by the CPU 308.

While the foregoing is directed to embodiments of the present disclosure, other and further embodiments of the disclosure may be devised without departing from the basic scope thereof.

1. A method of depositing a chalcogenide film atop a substrate in a hot wire chemical vapor deposition (HWCVD) process chamber, comprising:
vaporizing one or more liquid chalcogenide precursors while flowing a carrier gas to form a first gas mixture of the vaporized chalcogenide precursor and the carrier gas;
mixing the first gas mixture with a second gas to form a second gas mixture, wherein the second gas is a catalyst; and
flowing the second gas mixture to the HWCVD process chamber, wherein the second gas mixture dissociates in the HWCVD process chamber to deposit a chalcogenide film atop the substrate.

2. The method of claim 1, wherein the one or more liquid chalcogenide precursors is at least one of Ge(NMe₂)₄, Sb(NMe₂)₃, or Te(i-Pr)₂.

3. The method of claim 1, wherein the second gas is hydrogen.

4. The method of claim 1, wherein a flow rate of the carrier gas is about 100 sccm to about 2,000 sccm.

5. The method of claim 1, wherein a flow rate of the second gas is about 100 sccm to about 1,000 sccm.

6. The method of claim 1, wherein the carrier gas is an inert gas.

7. The method of claim 1, wherein a pressure within the HWCVD process chamber is about 1 Torr to about 30 Torr.

8. The method of claim 1, further comprising:
heating filaments of the HWCVD process chamber to a temperature of about 500 degrees Celsius to about 600 degrees Celsius.

9. A method of depositing a chalcogenide film atop a substrate in a hot wire chemical vapor deposition (HWCVD) process chamber, comprising:
vaporizing one or more liquid chalcogenide precursors while flowing a carrier gas to form a first gas mixture of the vaporized chalcogenide precursor and the carrier gas, wherein a flow rate of the carrier gas is about 100 sccm to about 2,000 sccm;
mixing the first gas mixture with a second gas to form a second gas mixture, wherein the second gas is a catalyst, wherein a flow rate of the second gas is about 100 sccm to about 1,000 sccm;
heating filaments of the HWCVD process chamber to a temperature of about 500 degrees Celsius to about 600 degrees Celsius; and
flowing the second gas mixture to the HWCVD process chamber, wherein the second gas mixture dissociates in the HWCVD process chamber to deposit a chalcogenide film atop the substrate.

10. The method of claim 9, wherein the one or more liquid chalcogenide precursors is at least one of Ge(NMe₂)₄, Sb(NMe₂)₃, or Te(i-Pr)₂.

11. The method of claim 9, wherein the second gas is hydrogen.

12. The method of claim 9, wherein a pressure within the HWCVD process chamber is about 1 Torr to about 30 Torr.

13. A non-transitory computer readable medium, having instructions stored thereon which, when executed, cause a process chamber to perform a method of depositing a chalcogenide film atop a substrate in a hot wire chemical vapor deposition (HWCVD) process chamber, comprising:
vaporizing one or more liquid chalcogenide precursors while flowing a carrier gas to form a first gas mixture of the vaporized chalcogenide precursor and the carrier gas;
mixing the first gas mixture with a second gas to form a second gas mixture, wherein the second gas is a catalyst; and
flowing the second gas mixture to the HWCVD process chamber, wherein the second gas mixture dissociates in the HWCVD process chamber to deposit a chalcogenide film atop the substrate.

14. The non-transitory computer readable medium of claim 13, wherein the one or more liquid chalcogenide precursors is at least one of Ge(NMe₂)₄, Sb(NMe₂)₃, or Te(i-Pr)₂.

15. The non-transitory computer readable medium of claim 13, wherein the second gas is hydrogen.

16. The non-transitory computer readable medium of claim 13, wherein a flow rate of the carrier gas is about 100 sccm to about 2,000 sccm.

17. The non-transitory computer readable medium of claim 13, wherein a flow rate of the second gas is about 100 sccm to about 1,000 sccm.

18. The non-transitory computer readable medium of claim 13, wherein the carrier gas is an inert gas.

19. The non-transitory computer readable medium of claim 13, wherein a pressure within the HWCVD process chamber is about 1 Torr to about 30 Torr.

20. The non-transitory computer readable medium of claim 13, further comprising:
heating filaments of the HWCVD process chamber to a temperature of about 500 to about 600 degrees Celsius.
